(19) United States
(12) Patent Application Publication
(10) Pub. No.: US 2007/0235796 A1
(43) Pub. Date: Oct. 11, 2007

(54) P-type doped nanowire and method of fabricating the same

(75) Inventors: Hyo-sug Lee, Gyeonggi-do (KR); Jong-seob Kim, Gyeonggi-do (KR); Noe-jung Park, Gyeonggi-do (KR); Sung-hoon Lee, Gyeonggi-do (KR); Young-gu Jin, Gyeonggi-do (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/224,288

(22) Filed: Sep. 13, 2005

(30) Foreign Application Priority Data
Sep. 13, 2004 (KR) 10-2004-0073087

(51) Int. Cl. H01L 29/788

(52) U.S. Cl. 257/315

(57) ABSTRACT

A p-type doped nanowire and a method of fabricating the same. The nanowire has a p-type doped portion which is formed by chemically binding a radical having a half-occupied outermost orbital shell to the corresponding portion of the nanowire, which corresponding portion of the nanowire donates an electron to the radical to thereby form the p-type doped portion.

### BACKGROUND OF THE INVENTION

This application claims the benefit of Korean Patent Application No. 10-2004-0073087, filed on Sep. 13, 2004, in the Korean Intellectual Property Office, the disclosure of which is incorporated herein in its entirety by reference.

1. Field of the Invention

The present invention relates to a p-type doped nanowire and a method of fabricating the same, and more particularly, to a nanowire having a p-type doped portion which is formed by chemically binding a radical having an unpaired electron in its outermost orbital shell to a corresponding portion of a n-type or an intrinsic nanowire and a method of fabricating the same.

2. Description of the Related Art

Nanowires may be used in many applications. Especially, much research has been conducted on their use in a light emitting diode (LED).

Japanese Patent Publication No. Hei 10-326888 discloses a light emitting device comprising a nanowire made of silicon and a method of fabricating the light emitting device. After a catalytic layer such as gold is deposited on a substrate, the silicon nanowire is grown from the catalytic layer by flowing silicon tetrachloride (SiCl₄) gas into a reactor. The silicon nanowire light emitting device can be manufactured at low cost. However, the silicon nanowire light emitting device has a low light emitting efficiency.

U.S. Patent Publication No. 2003/0168964 discloses a nanowire light emitting device having a p-n diode structure. In this case, the lower portion of the nanowire light emitting device is formed of an n-type nanowire and the upper portion is formed of a p-type nanowire, and the nanowire light emitting device emits light from the junction region of the two portions. Other components are added using a vapor phase-liquid phase-solid phase (VLS) method in order to fabricate the nanowire light emitting device having the p-n junction structure.

The nanowire light emitting device having the p-n junction structure is obtained by sequentially forming the p-type nanowire on the n-type nanowire, thus making it difficult to obtain a high quality p-n junction structure. That is, the semiconductor atom must be substituted with the impurity atom using ion implantation or diffusion in order to form the p-type nanowire. However, it is very difficult to obtain the p-type nanowire having a nano-sized diameter using this doping method.

In addition, when the nanowire is highly doped during its growth using a self-assembly method, the dopant may interfere with growth of the nanowire.

Thus, there is a need for a method of forming a p-type nanowire by doping after forming a nanowire.

### SUMMARY OF THE INVENTION

The present invention provides a nanowire having a p-type doped portion which is formed by chemically binding a radical having an unpaired electron in its outermost orbital shell to a corresponding portion of a n-type or an intrinsic nanowire and a method of fabricating the same.

According to a first aspect, the present invention provides a nanowire having a p-type doped portion formed by chemically binding a radical having a half-occupied outermost orbital shell to a corresponding portion of the nanowire, which corresponding portion of the nanowire donates an electron to the radical to thereby form said p-type doped portion.

The nanowire may be made of a material selected from the group consisting of ZnO, SnO₂, In₂O₃, NiO and GaN.

The radical may be one selected from the group consisting of a halogen atom, NO, NO₂ and an oxygen (O) atom.

The radical may be obtained by decomposing at least one compound selected from the group consisting of a peroxide compound, an azo compound, and a persulfate compound.

The radical may have at least one component selected from the group consisting of an alkyl group, an aryl group, a benzyl group, hydrogen and an alkali metal.

According to another aspect, the present invention provides a method of fabricating a p-type nanowire, comprising: placing a nanowire in a vacuum chamber; and forming a p-type doped portion by chemically binding a radical having a half-occupied outermost orbital shell to a circumferential portion of the nanowire.

The radical may be formed by flowing a gaseous source comprising at least one selected from the group consisting of a halogen atom, NO, NO₂ and an oxygen (O) atom into the vacuum chamber.

The step of forming a p-type doped portion may comprise: coating at least one compound selected from the group consisting of a peroxide compound, an azo compound and a persulfate compound onto a circumferential portion of the nanowire; and decomposing a bond in the coated compound by heating the vacuum chamber to a predetermined temperature or irradiating the coated compound to form the radical.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic view illustrating a method of p-type doping nanowires according to an embodiment of the present invention;

FIG. 2 is a view illustrating a principle of the p-type doping method according to an embodiment of the present invention;

FIGS. 3 through 5 are graphs showing the results of calculating the energy level of a ZnO nanowire to which radicals chemically bind, based on the density functional theory (DFT); and

FIG. 6 is a schematic view illustrating an apparatus for fabricating a p-type doped nanowire according to an embodiment of the present invention.

### DETAILED DESCRIPTION OF THE INVENTION

A p-type doped nanowire and a method of fabricating the same according to embodiments of the present invention will be described in detail with reference to the attached drawings. However, the present invention should not be construed as being limited thereto.

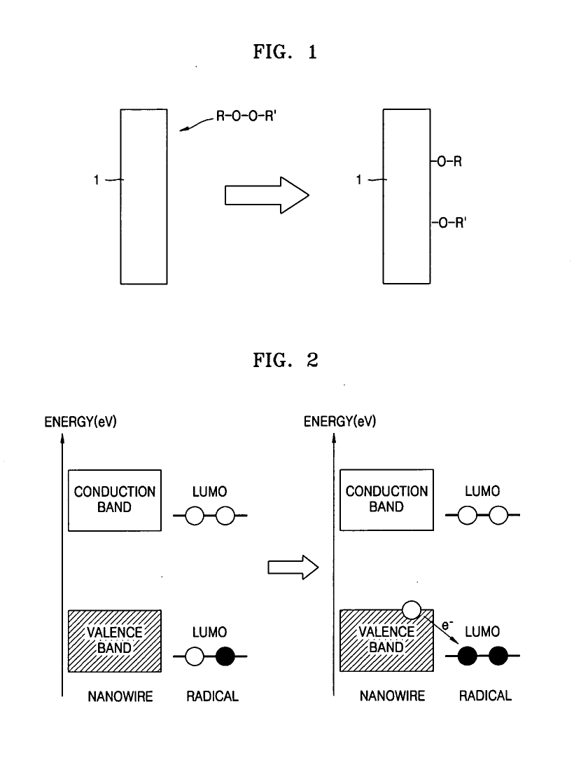

FIG. 1 is a schematic view illustrating a method of p-type doping nanowires according to an embodiment of the present invention.

Referring to FIG. 1, when a nanowire 1 composed of ZnO and having a predetermined diameter, for example, 20-100 nm, comes in contact with a R—O—O—R′ molecule (wherein each of R and R′ is alkyl, halogenated alkyl, aryl, benzyl, or hydrogen and which can be the same as or different from each other) while its internal bond O—O is decomposed, radicals O'R and O—R′ formed due to the decomposition chemically bind to a circumference of the nanowire 1. The radicals O—R and O—R′ have an unpaired electron in the outermost orbital shell. The radicals chemically bind to the nanowire 1 while attracting an electron from the nanowire 1. Thus, a portion of the nanowire 1 from which the electron has escaped is p-type doped.

Although ZnO is used as the nanowire in the above description, the nanowire for use in the present invention is not necessarily limited thereto. The nanowire has a wide band gap and may be made of a transparent conducting oxide, such as SnO₂, In₂O₃, and NiO, or GaN, etc.

FIG. 2 is a view illustrating a principle of the p-type doping method according to an embodiment of the present invention.

Referring to FIG. 2, when a radical having an unpaired electron in the highest occupied molecular orbital (HOMO), which has a lower energy level than that of a valence band of the nanowire, is bound to a surface of a nanowire, an electron in the valence band moves to an empty space of the HOMO, thereby forming a hole in the nanowire. In FIG. 2, LUMO (lowest unoccupied molecular orbital) represents an orbital having the lowest energy level among unoccupied orbitals.

Energy levels of HOMOs of an ZnO nanowire and radicals are shown in Table 1.

TABLE 1

| | |
|---|---|
| F | −17.39 |
| OH | −12.98 |
| CH₃COO | −11.16 |
| NO₂ | −9.39 |
| NO | −9.26 |
| ZnO | −8.0 |

The unit of the numerical values in Table 1 is eV.

As seen from Table 1, since the energy level of the valence band in ZnO, which is used as a nanowire, is higher than that of the outermost orbital shell in the radicals, the electron of ZnO can easily move to the orbital of the radicals.

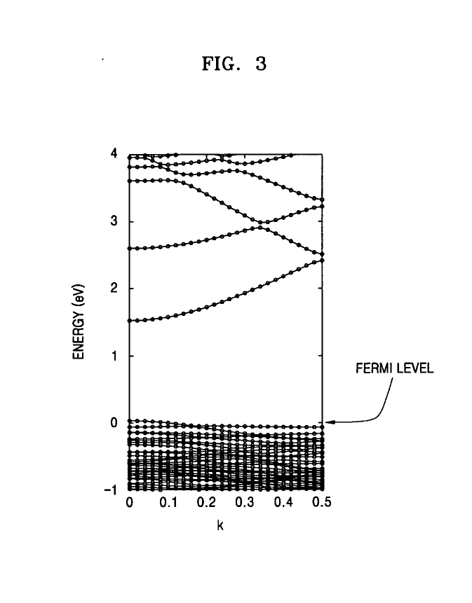

FIG. 3 is a graph showing the result of calculating the energy level of a ZnO nanowire to which a fluorine ion chemically binds, based on the density functional theory (DFT). It can be seen from FIG. 3 that the energy level of the valence band in the ZnO nanowire to which a fluorine ion binds is higher than the Fermi level, and thus, a hole can be formed in the nanowire. That is, an electron escapes from the ZnO nanowire, and thus, the ZnO nanowire is p-type doped. In FIG. 3, the x-axis represents a momentum space (k).

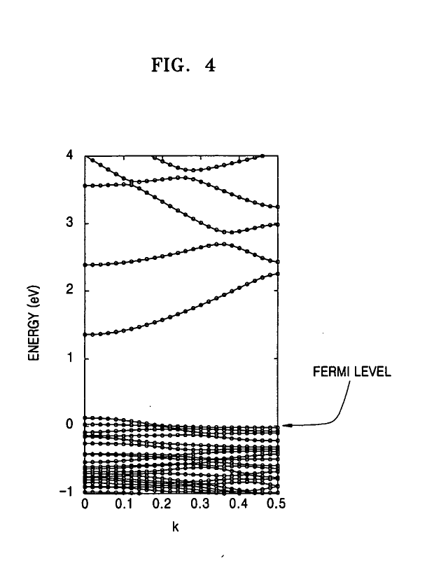

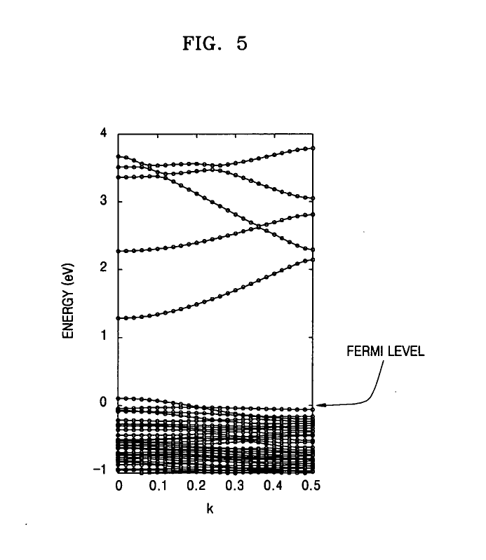

FIGS. 4 and 5 are graphs showing the energy levels of a product of a ZnO nanowire to which OH chemically binds and a product of a ZnO nanowire to which CH₃COO chemically binds, respectively. Both products exhibit a p-type doping property.

Although ZnO is used as the nanowire in the above description, the nanowire for use in the present invention is not necessarily limited thereto. For example, a transparent conducting oxide which has a wire band gap having a wide energy gap between a conduction band and a valence band, such as SnO₂, In₂O₃, and NiO, or a nanowire composed of GaN may be used as the nanowire.

The radical for use in the present invention is not limited to F, OH and CH₃COO. The nanowire may be p-type doped with NO, NO₂ and O, which have an unpaired electron in the outermost orbital shell.

The radical may be obtained by decomposing a peroxide compound (R—COO—OOC—R′ or R—O—O—R′), an azo compound (R—N═N—R′), or a persulfate compound (R—S—S—R or MxSyOz), wherein each of R and R′ is alkyl, halogenated alkyl, aryl, benzyl, or hydrogen and can be the same as or different from each other, M is an alkali metal, and each of x, y, and z represents an integer. When these compounds are subjected to a thermal reaction or light irradiation, internal chemical bonds are broken, thereby forming radicals, which are used in the p-type doping.

For example, for the peroxide compound having the structure of R—O——O—R′, the O—O bond is broken to form RO⁻ and R′O⁻. For the azo compound, N—N is changed into N₂ gas and the remaining portion becomes a radical.

Hereinafter, a method of fabricating a p-type doped nanowire using the radical will be described in detail.

The method comprises feeding a gas source of the radical into a chamber to react with the nanowire.

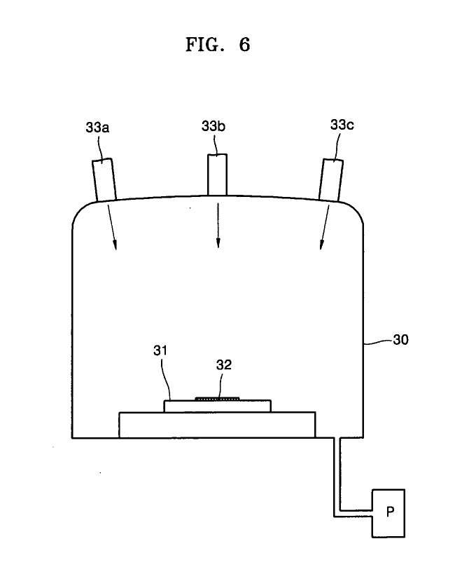

FIG. 6 is a schematic view illustrating an apparatus for fabricating a p-type doped nanowire according to an embodiment of the present invention. Referring to FIG. 6, a chamber 30 contains a specimen holder 31 and a specimen 32 is placed on the specimen holder 31. The specimen 32 may be a nanowire fabricated using a conventional method or an electronic device comprising the nanowire.

The method of fabricating a p-type nanowire will be described in detail.

First, the specimen 32 comprising a nanowire which is composed of ZnO is placed on the specimen holder 31. Impurities in the chamber 30 are removed using a vacuum pump P.

Then, a radical-forming gas, for example, a halogen gas is supplied to the chamber 30 through gas inlets 33a, 33b, and 33c. Examples of the halogen gas include F₂, Cl₂, Br₂, or I₂. The amount of gas supplied to the chamber 30 can be optionally controlled and is not specifically limited.

Then, the temperature in the chamber 30 is raised, for example, to about 300-600° C., using a temperature control unit (not shown). For a fluorine or chlorine gas, room temperature can be used. When a bromine gas or iodide gas is used, the gas source supplied through the gas inlets 33a, 33b, and 33c and the inside of the chamber 30 may be maintained at a high temperature. A halogen gas, such as fluorine gas, etc., is spontaneously decomposed as in reaction scheme 1 below, and receives an electron from the nanowire to form a chemical bond with the nanowire, to thereby stabilize the same.

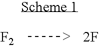

As a result, the nanowire to which a fluorine atom binds has lost the electron, thereby becoming p-type doped. FIGS. 3 through 5 show the energy levels of p-type doped nanowires.

NO, NO₂ and O, etc. may be also used as the radical in a gaseous state.

Another method of fabricating a p-type nanowire using a radical will now be described.

First, a compound selected from the group consisting of a peroxide compound, an azo compound, and a persulfate compound is coated on a circumference of the nanowire to be p-type doped. For example, a peroxide compound (R—O—O—R′) is coated on a surface of a ZnO nanowire.

Then, the specimen 32 comprising the nanowire which is coated with the peroxide compound is placed on the specimen holder 31. Impurities in the chamber 30 are removed using the vacuum pump P.

Then, the temperature in the chamber 30 is raised, for example, to about 60-80° C., using a temperature control unit (not shown). The radicals O—R and O—R′ formed due to the breaking of a bond O—O in the peroxide compound chemically bind to the nanowire 1 while attracting an electron from the nanowire 1, as illustrated in FIG. 1.

As a result, the nanowire to which the radicals generated from the peroxide compound bind loses the electron, thereby becoming p-type doped.

For an azo compound, N₂ gas leaves the azo compound with breaking of the bond, thereby forming a radical.

The nanowire having the p-type doped portion obtained using the above method can be used in a light emitting device, a field effect transistor, etc.

According to the present invention, a stable p-type doped nanowire can be fabricated by chemically binding a radical having a half-occupied outermost orbital shell to a n-type or an intrinsic nanowire, without using a conventional method, for example, ion implantation or diffusion. The p-type doped nanowire can be fabricated in a simplified process, and thus, an electronic device comprising the p-type doped nanowire can be mass-produced.

While the present invention has been particularly shown and described with reference to exemplary embodiments thereof, it will be understood by those of ordinary skill in the art that various changes in form and detail may be made therein without departing from the spirit and scope of the present invention as defined by the following claims.

1. A nanowire having a p-type doped portion which is formed by chemically binding a radical having an unpaired electron in an outermost orbital shell thereof to a corresponding portion of the nanowire, which corresponding portion of the nanowire donates an electron to the radical to thereby form said p-type doped portion, and
wherein the radical is selected from the group consisting of a halogen atom, NO NO₂ and an oxygen (O) atom.

2. The nanowire of claim 1, wherein the nanowire is made of a material selected from the group consisting of ZnO, SnO₂, In₂O₃, NiO and GaN.

3. (canceled)

4. A nanowire having a p-type doped portion which is formed by chemically binding a radical having an unpaired electron in an outermost orbital shell thereof to a corresponding portion of the nanowire, which corresponding portion of the nanowire donates an electron to the radical to thereby form said p-type doped portion, and
wherein the radical is obtained by decomposing at least one compound selected from the group consisting of a peroxide compound, an azo compound and a persulfate compound.

5. The nanowire of claim 4, wherein the radical has at least one component selected from the group consisting of an alkyl group, an aryl group, a benzyl group, hydrogen and an alkali metal.

6. A method of fabricating a nanowire having a p-type doped portion which is formed by chemically binding a radical having an unpaired electron in an outermost orbital shell thereof to a corresponding portion of the nanowire, which corresponding portion of the nanowire donates an electron to the radical to thereby form said p-type doped portion, and wherein the radical is selected from the group consisting of a halogen atom, NO, NO₂ and an oxygen (O) atom, said method comprising:
placing a nanowire in a vacuum chamber;
forming a p-type doped portion by chemically binding a radical having an unpaired electron in an outermost orbital shell thereof to a circumferential portion of the nanowire; and
wherein the radical is formed by flowing a gas source comprising at least one selected from the group consisting of a halogen atom, NO, NO₂ and an oxygen (O) atom into the vacuum chamber.

7. The method of claim 6, wherein the nanowire is made of a material selected from the group consisting of ZnO, SnO₂, In₂O₃, NiO and GaN.

8. (canceled)

9. (canceled)

10. The method of claim 6, wherein the halogen atom is fluorine.

11. A method of fabricating a nanowire having a p-type doped portion which is formed by chemically binding a radical having an unpaired electron in an outermost orbital shell thereof to a corresponding portion of the nanowire, which corresponding portion of the nanowire donates an electron to the radical to thereby form said p-type doped portion, and wherein the radical is obtained by decomposing at least one compound selected from the group consisting of a peroxide compound, an azo compound and a persulfate compound, said method comprising:
placing a nanowire in a vacuum chamber; and
forming a p-typed doped portion by chemically bonding a radical having an unpaired electron in an outermost orbital shell thereof to a circumferential portion of the nanowire
wherein the step of forming a p-typed portion comprises:
coating at least one compound selected from the group consisting of a peroxide compound, an azo compound and a persulfate compound to a circumferential portion of the nanowire; and
decomposing a bond in the coated compound by heating the vacuum chamber to a predetermined temperature or irradiating the coated compound to form the radical.

12. The method of claim 11, wherein the radical has at least one component selected from the group consisting of an alkyl group, an aryl group, a benzyl group, hydrogen and an alkali metal.

13. The nanowire of claim 4, wherein the nanowire is made of a material selected from the group consisting of ZnO, SnO₂, In₂O₃, NiO and GaN.

14. The nanowire of claim 5, wherein the nanowire is made of a material selected from the group consisting of ZnO, SnO₂, In₂O₃, NiO and GaN.

15. The method of claim 11, wherein the nanowire is made of a material selected from the group consisting of ZnO, SnO₂, In₂O₃, NiO and GaN.
